(19) United States
(12) Patent Application Publication
(10) Pub. No.: US 2018/0027344 A1
(43) Pub. Date: Jan. 25, 2018

(54) FOLDED STACKED PACKAGE WITH EMBEDDED DIE MODULE

(71) Applicants: John E. Dzarnoski, JR., Watertown, MN (US); Susie Johansson, Minneapolis, MN (US)

(72) Inventors: John E. Dzarnoski, JR., Watertown, MN (US); Susie Johansson, Minneapolis, MN (US)

(21) Appl. No.: 15/213,986

(22) Filed: Jul. 19, 2016

(51) Int. Cl. H04R 25/00; H05K 3/30; H05K 1/18

(52) U.S. Cl. CPC H04R 25/60; H05K 1/189; H05K 1/182; H05K 1/181; H05K 3/305; H04R 25/658; H05K 2201/056; H05K 2201/10083

(57) ABSTRACT

Described herein are an electronic device and method for constructing same in which a rolled stacked electronic package includes one or more surface mounted embedded die modules. When the package is folded, the embedded die module and another surface mounted module are in contact with one another. The package increases circuit density and reduces microelectronic circuit size.

### FIELD OF THE INVENTION

This invention pertains to electronic hearing assistance devices, hearing aid systems, and methods for their construction.

### BACKGROUND

Hearing assistance devices such as hearing aids are electronic devices that compensate for hearing losses amplifying and compressing sound, usually in a frequency selective manner. The electronic components of a hearing assistance device may include a microphone for receiving ambient sound, processing circuitry for processing the microphone signal in a manner that depends upon the frequency and amplitude of the microphone signal, an output transducer or receiver for converting the amplified microphone signal to sound for the wearer, and a battery for powering the components. Hearing assistance devices may also incorporate wireless transceivers for enabling communication with an external device and/or communication between two hearing instruments worn by a user.

Wearable hearing assistance devices such as hearing aids are designed with a small package size to both increase comfort and provide a less conspicuous appearance. In order to achieve the smallest hearing aid designs possible there is a need to develop smaller, denser micro-electronic packaging technologies.

### BRIEF DESCRIPTION OF THE DRAWINGS

FIG. 1 shows the basic electronic components of an example hearing assistance device.

FIGS. 2A-2C show a stacked package assembly in an unfolded state.

FIGS. 3A-3B show a stacked package assembly in a folded state.

### DETAILED DESCRIPTION

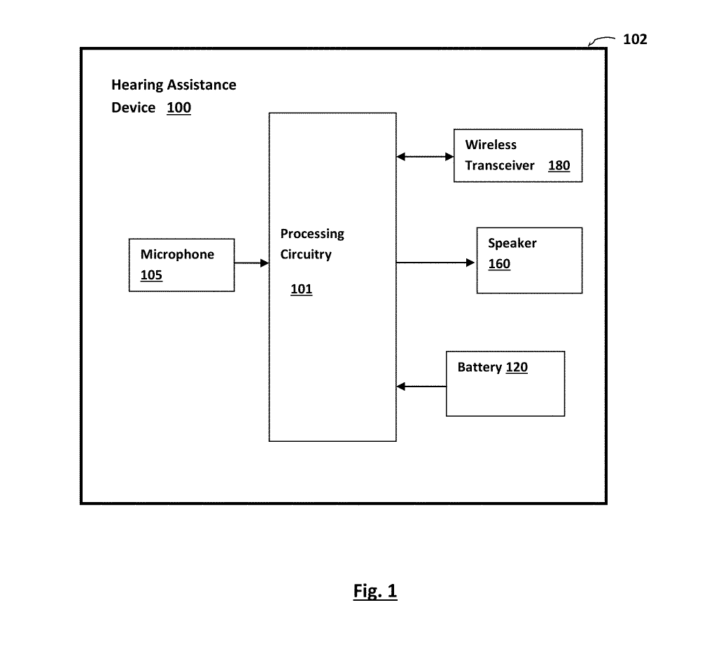

The electronic components of a hearing aid may include a microphone for receiving ambient sound, processing circuitry for amplifying the microphone signal in a manner that depends upon the frequency and amplitude of the microphone signal, a speaker for converting the amplified microphone signal to sound for the wearer, and a battery for powering the components. FIG. 1 illustrates the basic functional components of an example hearing assistance device 100 such as a hearing aid. The electronic circuitry of the device may be contained within a housing 102 that may be placed, for example, in the external ear canal or behind the ear. A battery 120 supplies power to the electronic circuitry. A microphone 105 receives sound waves from the environment and converts the sound into an input signal. The input signal may then be amplified by a pre-amplifier and sampled and digitized by an A/D converter to result in a digitized input signal. The device's processing circuitry 101 (e.g., which may include a digital signal processor or DSP) processes the digitized input signal into an output signal in a manner that compensates for the patient's hearing deficit. The processing circuitry 101 may be implemented in a variety of different ways, such as with an integrated digital signal processor or with a mixture of discrete analog and digital components that include a processor executing programmed instructions contained in a memory. The output signal is then passed to an audio output stage that drives speaker 160 (also referred to as a receiver) to convert the output signal into an audio output. In various embodiments, the hearing assistance device electronics including the processing circuitry 101 are enclosed in a housing 102 designed to be worn behind or about the wearer's ear and the receiver is positioned in the ear or the ear canal of the wearer.

The example device illustrated by FIG. 1 also includes a wireless transceiver 180 is interfaced to the hearing aid's processing circuitry and connected to the feedpoint of an antenna or antennas (not shown) for transmitting and/or receiving radio signals. The wireless transceiver 180 may enable ear-to-ear communications between the two hearing aids as well as communications with an external device. When receiving an audio signal from an external source, the wireless receiver 180 may produce a second input signal for the processing circuitry that may be combined with the input signal produced by the microphone 105 or used in place thereof.

Described herein are an electronic device and method for constructing same in which a rolled stacked electronic package includes one or more surface mounted embedded die modules. The package may be folded so that the embedded die module and another surface mounted module are adjacent one another in the folded state. In some embodiments, the package is folded so that the embedded die module and another surface mounted module are in close proximity or in contact with one another. The package increases circuit density and reduces microelectronic circuit size.

As the performance of electronic devices is increased, devices such as hearing assistance devices are becoming increasingly lightweight, thin and small. In accordance with this trend, an increasing number of electronic devices have been mounted on or embedded in printed circuit boards. A technique of mounting electronic devices on boards is referred to as surface mount technology, and a technique of embedding electronic devices in boards is referred to as embedded die technology or chip-in-flex.

The integration of various types of modules into a single electronic device involves mounting various electronic devices on system boards. The types of electronic devices that can be mounted together on system boards are not limited to active devices, and include passive devices. Examples of active devices include integrated circuit (IC) chips such as a memory chip, a logic chip, an image sensor and the like. Examples of passive devices include capacitors, resistors such as a pull-up resistor, a pull-down resistor and the like, inductors, antennas, and micro-electro-mechanical systems (MEMS) devices.

Stacked packages are largely classified into a package-on-package, a package-in-package, and a folded stacked package. The package-on-package is a stacked package structure in which one or more upper packages are stacked on top of a lower package and the upper packages and the lower package are electrically connected by solder balls, and the package-in-package is a stacked package structure in which a package is deposited inside another package, and particularly, on the electronic devices on the other package and the two packages are electrically connected through wire bonding. The package-on-package and the package-in-package are desirable in that they can directly adopt existing single package structures. However, the package-on-package and the package-in-package are relatively complicated stacked structures and could have poor electrical connections between packages. Also, wire bond connections with higher inductance may result in poorer performance.

The folded stacked package is a structure in which packaged or unpackaged electronic devices are mounted on or attached onto a folded flexible board or substrate. The folded stacked package has a relatively simple structure because the flexible board or substrate is folded after disposing or mounting electronic devices thereon. In addition, since electronic devices or packages in the folded stacked package are electrically connected through the flexible board or substrate, the folded stacked package is highly reliable in terms of electrical connections between the electronic devices or the packages.

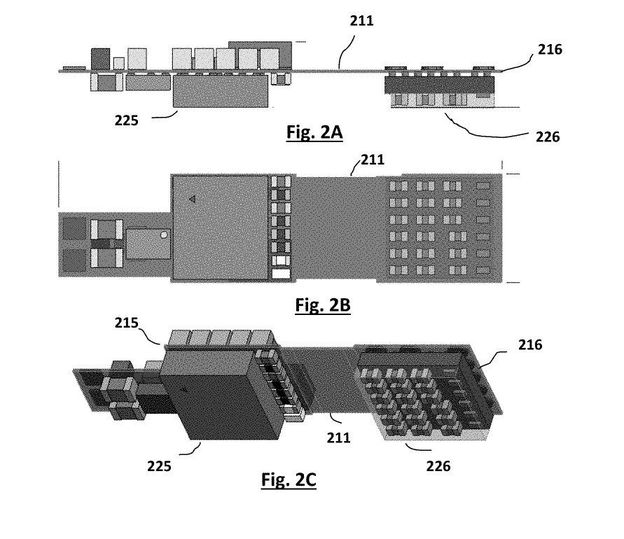

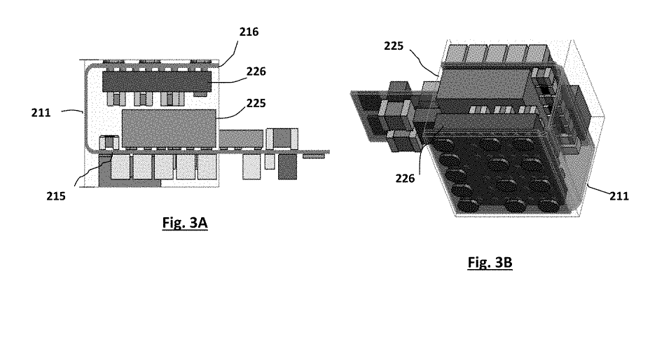

FIGS. 2A through 2C show a stacked package in side, bottom, and perspective views, respectively, before folding. The stacked package includes a flexible circuit board that comprises a folding unit 211, a first device packaging unit 215, and second device packaging unit 216. The first and second device packaging units are connected by the folding unit and have wiring patterns formed thereon. The first device packaging unit 215 has a first device 225 surface mounted thereon, and the second device packaging unit 216 has a second device 226 surface mounted thereon. Neither of the first or second devices are embedded in the flexible board. One of the devices 225 or 226, however, may be an embedded die module with the other device being either an embedded die module or other multi-component package. An embedded die module is a module where the device is placed or formed on an inner layer of a substrate so as to be buried therein. The device 225 is shown in the figures as an embedded die device while the device 226 is another type of multi-component package. After surface mount assembly, the package is folded. FIGS. 3A and 3B show the folded stacked package in side and perspective views, respectively. The assembly may be folded so that the first device 225 and second device 226 have their top surfaces in contact with each other. An adhesive may then be applied between the top surfaces of devices 225 and 226 to hold the package together. In other embodiments, the assembly may be folded so that the first device 225 and second device 226 have their top surfaces are adjacent one another but not in contact.

### Example Embodiments

In Example 1, an electronic device, comprises: a flexible circuit board that includes a first device packaging unit, a second device packaging unit and a folding unit; wherein the first and second device packaging units are connected by the folding unit and have wiring patterns formed thereon; a first device surface mounted on the first device packaging unit; a second device surface mounted on the second device packaging unit; wherein at least one of the first or second devices is an embedded die module; and, wherein the folding unit of the flexible circuit board is folded so that the top surfaces of the first and second devices are adjacent one another.

In Example 2, the subject matter of any of the Examples herein may optionally include wherein the folding unit of the flexible circuit board is folded so that the top surfaces of the first and second devices are in contact with one another.

In Example 3, the subject matter of any of the Examples herein may optionally include wherein an adhesive is applied between the top surfaces of the first and second devices.

In Example 4, the subject matter of any of the Examples herein may optionally include wherein the first and second devices are both embedded die modules.

In Example 5, a method for constructing an electronic device, comprises:

providing a flexible circuit board that includes a first device packaging unit, a second device packaging unit and a folding unit, wherein the first and second device packaging units are connected by the folding unit and have wiring patterns formed thereon; surface mounting a first device on the first device packaging unit; surface mounting a second device on the second device packaging unit; wherein at least one of the first or second devices is an embedded die module; and, folding the folding unit of the flexible circuit board so that the top surfaces of the first and second devices are adjacent one another.

In Example 6, the subject matter of any of the Examples herein may optionally include folding the folding unit of the flexible circuit board so that the top surfaces of the first and second devices are in contact one another.

In Example 7, the subject matter of any of the Examples herein may optionally include applying an adhesive between the top surfaces of the first and second devices.

In Example 8, a hearing assistance device, comprises: a microphone to convert an audio input into an input signal; processing circuitry to process the input signal into an output signal in a manner that compensates for the patient's hearing deficit; wherein the processing circuitry comprises: a flexible circuit board that includes a first device packaging unit, a second device packaging unit and a folding unit; wherein the first and second device packaging units are connected by the folding unit and have wiring patterns formed thereon; a first device surface mounted on the first device packaging unit; a second device surface mounted on the second device packaging unit; wherein at least one of the first or second devices is an embedded die module; and, wherein the folding unit of the flexible circuit board is folded so that the top surfaces of the first and second devices are adjacent one another.

In Example 9, a method for constructing a hearing assistance device, comprises: providing processing circuitry that comprises a flexible circuit board that includes a first device packaging unit, a second device packaging unit and a folding unit, wherein the first and second device packaging units are connected by the folding unit and have wiring patterns formed thereon; surface mounting a first device on the first device packaging unit; surface mounting a second device on the second device packaging unit; wherein at least one of the first or second devices is an embedded die module; folding the folding unit of the flexible circuit board so that the top surfaces of the first and second devices are adjacent one another; and, disposing within a housing a microphone to convert an audio input into an input signal and the processing circuitry configured to process the input signal into an output signal in a manner that compensates for the patient's hearing deficit.

In Example 10, the subject matter of any of the Examples herein may optionally include wherein the hearing assistance device is a behind-the-ear (BTE) hearing aid.

In Example 11, the subject matter of any of the Examples herein may optionally include wherein the hearing assistance device is an in-the-canal (ITC) hearing aid.

In Example 12, the subject matter of any of the Examples herein may optionally include wherein the hearing assistance device is a receiver-in-canal (RIC) hearing aid.

In Example 13, the subject matter of any of the Examples herein may optionally include wherein the hearing assistance device is a completely-in-the-canal (CIC) hearing aid.

It is understood that digital hearing aids may include a processor. In digital hearing aids with a processor, programmable gains may be employed to adjust the hearing aid output to a wearer's particular hearing impairment. The processor may be a digital signal processor (DSP), microprocessor, microcontroller, other digital logic, or combinations thereof. The processing may be done by a single processor, or may be distributed over different devices. The processing of signals referenced in this application can be performed using the processor or over different devices. Processing may be done in the digital domain, the analog domain, or combinations thereof. Processing may be done using subband processing techniques. Processing may be done using frequency domain or time domain approaches. Some processing may involve both frequency and time domain aspects. For brevity, in some examples drawings may omit certain blocks that perform frequency synthesis, frequency analysis, analog-to-digital conversion, digital-to-analog conversion, amplification, buffering, and certain types of filtering and processing. In various embodiments the processor is adapted to perform instructions stored in one or more memories, which may or may not be explicitly shown. Various types of memory may be used, including volatile and nonvolatile forms of memory. In various embodiments, the processor or other processing devices execute instructions to perform a number of signal processing tasks. Such embodiments may include analog components in communication with the processor to perform signal processing tasks, such as sound reception by a microphone, or playing of sound using a receiver (i.e., in applications where such transducers are used). In various embodiments, different realizations of the block diagrams, circuits, and processes set forth herein can be created by one of skill in the art without departing from the scope of the present subject matter.

It is further understood that different hearing assistance devices may embody the present subject matter without departing from the scope of the present disclosure. The devices depicted in the figures are intended to demonstrate the subject matter, but not necessarily in a limited, exhaustive, or exclusive sense. It is also understood that the present subject matter can be used with a device designed for use in the right ear or the left ear or both ears of the wearer.

The present subject matter is demonstrated for hearing assistance devices, including hearing aids, including but not limited to, behind-the-ear (BTE), in-the-ear (ITE), in-the-canal (ITC), receiver-in-canal (RIC), or completely-in-the-canal (CIC) type hearing aids. It is understood that behind-the-ear type hearing aids may include devices that reside substantially behind the ear or over the ear. Such devices may include hearing aids with receivers associated with the electronics portion of the behind-the-ear device, or hearing aids of the type having receivers in the ear canal of the user, including but not limited to receiver-in-canal (RIC) or receiver-in-the-ear (RITE) designs.

This application is intended to cover adaptations or variations of the present subject matter. It is to be understood that the above description is intended to be illustrative, and not restrictive. The scope of the present subject matter should be determined with reference to the appended claims, along with the full scope of legal equivalents to which such claims are entitled.

1. An electronic device, comprising:
a flexible circuit board that includes a first device packaging unit, a second device packaging unit and a folding unit;
wherein the first and second device packaging units are connected by the folding unit and have wiring patterns formed thereon;
a first device surface mounted on the first device packaging unit;
a second device surface mounted on the second device packaging unit;
wherein at least one of the first or second devices is an embedded die module;
wherein the folding unit of the flexible circuit board is folded so that the top surfaces of the first and second devices are adjacent one another;
wherein the folding unit of the flexible circuit board is folded so that the top surfaces of the first and second devices are in contact with one another and wherein an adhesive is applied between the top surfaces of the first and second devices.

2. (canceled)

3. (canceled)

4. The device of claim 1 wherein the first and second devices are both embedded die modules.

5. A method for constructing an electronic device, comprising:
providing a flexible circuit board that includes a first device packaging unit, a second device packaging unit and a folding unit, wherein the first and second device packaging units are connected by the folding unit and have wiring patterns formed thereon;
surface mounting a first device on the first device packaging unit;
surface mounting a second device on the second device packaging unit;
wherein at least one of the first or second devices is an embedded die module; folding the folding unit of the flexible circuit board so that the top surfaces of the first and second devices are adjacent one another; and
folding the folding unit of the flexible circuit board so that the top surfaces of the first and second devices are in contact one another and applying an adhesive between the top surfaces of the first and second devices.

6. (canceled)

7. (canceled)

8. The method of claim 5 wherein the first and second devices are both embedded die modules.

9. A hearing assistance device, comprising:
a microphone to convert an audio input into an input signal;
processing circuitry to process the input signal into an output signal in a manner that compensates for the patient's hearing deficit;
wherein the processing circuitry comprises:
a flexible circuit board that includes a first device packaging unit, a second device packaging unit and a folding unit;
wherein the first and second device packaging units are connected by the folding unit and have wiring patterns formed thereon;
a first device surface mounted on the first device packaging unit;
a second device surface mounted on the second device packaging unit;
wherein at least one of the first or second devices is an embedded die module;
wherein the folding unit of the flexible circuit board is folded so that the top surfaces of the first and second devices are adjacent one another; and,
wherein the folding unit of the flexible circuit board is folded so that the top surfaces of the first and second devices are in contact with one another and wherein an adhesive is applied between the top surfaces of the first and second devices.

10. (canceled)

11. (Cancelled)

12. The device of claim 9 wherein the first and second devices are both embedded die modules.

13. A method for constructing a hearing assistance device, comprising:
providing processing circuitry that comprises a flexible circuit board that includes a first device packaging unit, a second device packaging unit and a folding unit, wherein the first and second device packaging units are connected by the folding unit and have wiring patterns formed thereon;
surface mounting a first device on the first device packaging unit;
surface mounting a second device on the second device packaging unit;
wherein at least one of the first or second devices is an embedded die module;
folding the folding unit of the flexible circuit board so that the top surfaces of the first and second devices are adjacent one another;
disposing within a housing a microphone to convert an audio input into an input signal and the processing circuitry configured to process the input signal into an output signal in a manner that compensates for the patient's hearing deficit; and,
folding the folding unit of the flexible circuit board so that the top surfaces of the first and second devices are in contact one another and applying an adhesive between the top surfaces of the first and second devices.

14. (canceled)

15. (canceled)

16. The method of claim 13 wherein the first and second devices are both embedded die modules.

17. The method of claim 13 wherein the hearing assistance device is a behind-the-ear (BTE) hearing aid.

18. The method of claim 13 wherein the hearing assistance device is an in-the-canal (ITC) hearing aid.

19. The method of claim 13 wherein the hearing assistance device is a receiver-in-canal (RIC) hearing aid.

20. The method of claim 13 wherein the hearing assistance device is a completely-in-the-canal (CIC) hearing aid.
